(19) United States
(12) Patent Application Publication
(10) Pub. No.: US 2015/0294869 A1
(43) Pub. Date: Oct. 15, 2015

(54) METHOD FOR MANUFACTURING LOW-TEMPERATURE POLYSILICON THIN FILM TRANSISTOR AND ARRAY SUBSTRATE

(71) Applicant: BOE Technology Group Co., Ltd., Beijing (CN)

(72) Inventor: Xue Mao, Beijing (CN)

(21) Appl. No.: 14/436,142

(22) PCT Filed: Mar. 31, 2014
(86) PCT No.: PCT/CN2014/074421

§ 371 Date: Apr. 16, 2015

(30) Foreign Application Priority Data
Feb. 24, 2014 (CN) 201410062525.8

(51) Int. Cl. H01L 21/225; H01L 49/02; H01L 27/12; H01L 29/66; H01L 21/02

(52) U.S. Cl. CPC H01L 21/2254; H01L 29/66969; H01L 21/02667; H01L 27/1274; H01L 28/60

(57) ABSTRACT

The present invention discloses a method for manufacturing a low-temperature polysilicon thin film transistor and an array substrate, which is used for simplifying manufacturing process procedures of the thin film transistor. The method includes steps of: forming an a-Si layer on a substrate; forming an impurity film on the a-Si layer, positions of the impurity film corresponding to a source doping layer to be formed and a drain doping layer to be formed respectively; and converting the a-Si layer into a polysilicon layer, and during the conversion from the a-Si layer into the polysilicon layer, ions in the impurity film being implanted into regions in the polysilicon layer contacting with the impurity film to form the source doping layer and the drain doping layer. In particular, an excimer laser annealing process is performed on the a-Si layer and the impurity film, so that the source doping layer is formed in a region corresponding to the source doping layer to be formed, the drain doping layer is formed in a region corresponding to the drain doping layer to be formed and the polysilicon layer is formed in regions except the source doping layer and the drain doping layer.

### CROSS-REFERENCE TO RELATED APPLICATION

This Application is a Section 371 National Stage Application of International Application No. PCT/CN2014/074421, filed Mar. 31, 2014, which has not yet published, which claims priority to Chinese Patent Application No. 201410062525.8, filed Feb. 24, 2015, in Chinese, the contents of which are hereby incorporated by reference in their entirety.

### BACKGROUND OF THE INVENTION

1. Field of the Invention

The present disclosure relates to a manufacturing process for thin film transistor, in particular, to a method for manufacturing a low-temperature polysilicon thin film transistor and an array substrate.

2. Description of the Related Art

A thin film transistor (TFT) by applying a driving voltage to drive the display device is widely used in pixel units of various display devices. An amorphous silicon (a-Si) material with good stability and processability is usually used in an active layer of the TFT, however, a requirement of a large size and high resolution display device, in particular, a requirement of a next-generation active matrix organic light emitting device (AMOLED), cannot be met due to a lower carrier mobility of the a-Si material. Compared with an amorphous silicon (a-Si) thin film transistor, the polysilicon thin film transistor, especially the low-temperature polysilicon thin film transistor, which has a higher electron mobility and lower leakage current, has gradually replaced the amorphous silicon thin film transistor and become the mainstream technique of the thin film transistor.

For the prior art technology, in the process of forming the low-temperature polysilicon thin film transistor, a doping for forming a source doping layer and a drain doping layer is performed by forming the polysilicon layer, ion implanting to the source doping layer and the drain doping layer and carrying out an annealing process in sequence.

Therefore, the polysilicon, the source doping layer and the drain doping layer are formed in two process steps, so that forming steps for the low-temperature polysilicon are complicated. Moreover, the ion implantation for forming regions of the source doping layer and the drain doping layer will lead to some defects and undesirable effects of the thin film transistor, thus the thin film transistor has a poor performance and a lower rate of high quality product.

### SUMMARY OF THE INVENTION

It is intended to provide the present invention to overcome at least one aspect of the defects in the prior art.

According to an exemplary embodiment of the present invention, provided is a method for manufacturing a low-temperature polysilicon thin film transistor comprising steps of: forming an a-Si layer on a substrate; forming an impurity film on the a-Si layer, positions of the impurity film corresponding to a source doping layer to be formed and a drain doping layer to be formed respectively; and converting the a-Si layer into a polysilicon layer, and during the conversion from the a-Si layer into the polysilicon layer, ions in the impurity film being implanted into regions in the polysilicon layer contacting with the impurity film to form the source doping layer and the drain doping layer.

According to another exemplary embodiment of the present invention, provided is a method for manufacturing an array substrate comprising steps of: forming an a-Si layer on a substrate; forming an impurity film on the a-Si layer, positions of the impurity film corresponding to a source doping layer to be formed, a drain doping layer to be formed and a bottom electrode of a storage capacitance to be formed respectively; converting the a-Si layer into a polysilicon layer, and during the conversion from the a-Si layer into the polysilicon layer, ions in the impurity film being implanted into regions in the polysilicon layer contacting with the impurity film to form the source doping layer, the drain doping layer and the bottom electrode of the storage capacitance.

Alternatively, in the step of the conversion from the a-Si layer into the polysilicon layer in the method for manufacturing the low-temperature polysilicon thin film transistor, an excimer laser annealing process is performed on the a-Si layer and the impurity film, so that the source doping layer is formed in a region corresponding to the source doping layer to be formed, the drain doping layer is formed in a region corresponding to the drain doping layer to be formed and the polysilicon layer is formed in regions except the source doping layer and the drain doping layer.

Alternatively, in the step of the conversion from the a-Si layer into the polysilicon layer in the method for manufacturing the array substrate, an excimer laser annealing process is performed on the a-Si layer and the impurity film, so that the source doping layer is formed in a region corresponding to the source doping layer to be formed, the drain doping layer is formed in a region corresponding to the drain doping layer to be formed, the bottom electrode of the storage capacitance is formed in a region corresponding to the bottom electrode of the storage capacitance to be formed and the polysilicon layer is formed in regions except the source doping layer, the drain doping layer and the bottom electrode of the storage capacitance.

Alternatively, in above methods, the excimer laser annealing process is performed under conditions of: a laser pulse frequency being 100-400 Hz, a laser overlapping rate being 90%-98%, a laser pulse width being less than 100 ns and a laser energy density being 100-600 mJ/cm².

The above methods may also comprise a step of: patterning the polysilicon layer to form an active layer in a predetermined region.

Alternatively, in above methods, a thermal annealing process is performed on the a-Si layer, wherein the step of thermally annealing the a-Si layer is after the step of forming the a-Si layer and before the step of forming the impurity film.

Alternatively, in the method for manufacturing the low-temperature polysilicon thin film transistor, the step of forming the impurity film comprises steps of: forming a boron film or phosphorus film on the a-Si layer by a thermal evaporation or sputtering method, and forming the impurity film by leaving, by a patterning process, the boron film or phosphorus film in regions corresponding to the source doping layer and drain doping layer. Further alternatively, the thickness of the boron film or phosphorus film is controlled or selected such that ions in the boron film or phosphorus film are completely implanted into the polysilicon layer.

Alternatively, in the method for manufacturing the array substrate, the step of forming the impurity film comprises steps of: forming a boron film or phosphorus film on the a-Si layer by a thermal evaporation or sputtering method, and forming the impurity film by leaving, by a patterning process, the boron film or phosphorus film in regions corresponding to the source doping layer, the drain doping layer and the bottom electrode of the storage capacitance. Further alternatively, the thickness of the boron film or phosphorus film is controlled or selected such that ions in the boron film or phosphorus film are completely implanted into the polysilicon layer.

Alternatively, the method for manufacturing the low-temperature polysilicon thin film transistor further comprising a step of: removing the redundant impurity film from the surface of the polysilcion layer after forming the source doping layer and the drain doping layer.

Alternatively, the method for manufacturing the array substrate further comprising a step of: removing the redundant impurity film from the surface of the polysilcion layer after forming the source doping layer, the drain doping layer and the bottom electrode of the storage capacitance.

Alternatively, the step of forming the a-Si layer on the substrate comprises a step of: depositing the a-Si layer on a buffer layer formed on the substrate or directly on the substrate by a film forming process.

The present invention also relates to a method for manufacturing a low-temperature polysilicon thin film transistor comprising a step of: forming a source doping layer and a drain doping layer while forming a polysilicon layer.

In the method for manufacturing the low-temperature polysilicon thin film transistor according to the present invention, the source doping layer and the drain doping layer are formed during forming the polysilicon layer, specifically, the source doping layer and the drain doping layer are formed while the polysilicon is formed by the excimer laser annealing (ELA), thus the manufacturing process is simplified, moreover, doping ions forming the source doping layer and the drain doping layer are formed by the excimer laser annealing, which avoids the defects and undesirable effects of the thin film transistor caused by the ion implanting in the prior art, thus the performance of the thin film transistor is improved.

### BRIEF DESCRIPTION OF THE DRAWINGS

FIG. 1 is a flow chart forming an active layer, a source doping layer and a drain doping layer of a low-temperature polysilicon thin film transistor according to an exemplary embodiment of the present invention;

FIG. 2 is a flow chart forming an array substrate according to an exemplary embodiment of the present invention;

FIG. 3 is a structural schematic view of a substrate with a buffer layer formed thereon according to an exemplary embodiment of the present invention;

FIG. 4 is a structural schematic view of a substrate with a-Si formed thereon according to an exemplary embodiment of the present invention;

FIG. 5 is a structural schematic view of a substrate with an impurity film formed on the a-Si according to an exemplary embodiment of the present invention;

FIG. 6 is a structural schematic view of a substrate with an impurity film formed on regions of the a-Si layer corresponding to the source doping layer, the drain doping layer and a bottom electrode of a storage capacitance according to an exemplary embodiment of the present invention;

FIG. 7 is a structural schematic view of a substrate with the source doping layer, the drain doping layer and the bottom electrode of the storage capacitance formed thereon according to an exemplary embodiment of the present invention;

FIG. 8 is a structural schematic view of a substrate with an active layer formed thereon according to an exemplary embodiment of the present invention;

FIG. 9 is a structural schematic view of a substrate with a gate insulating layer, a gate electrode and a top electrode of the storage capacitance formed thereon according to an exemplary embodiment of the present invention;

FIG. 10 is a structural schematic view of a substrate with a first insulating layer, a source electrode, a drain electrode and a bottom electrode lead formed thereon according to an exemplary embodiment of the present invention;

FIG. 11 is a structural schematic view of a substrate with a second insulating layer and a pixel electrode formed thereon according to an exemplary embodiment of the present invention.

### DETAILED DESCRIPTION OF PREFERRED EMBODIMENTS OF THE INVENTION

The present invention will be described sufficiently with reference to preferable embodiments of the present invention and accompanying drawings, however, before this description, it will be appreciated by those skilled in the art that the present invention described herein may be modified while obtaining an effect of the present invention. Thus, it should be understood for those skilled in the art that the following description is only a wide revelation, and the contents thereof is not intended to limit the exemplary embodiments described in the present invention.

The method for manufacturing the low-temperature polysilicon thin film transistor and array substrate according to exemplary embodiments is used to simplify the manufacturing process of the thin film transistor and to increase the performance of the thin film transistor.

In the method for manufacturing the low-temperature polysilicon thin film transistor according to exemplary embodiments of the present invention, the source doping layer and the drain doping layer are formed during forming the polysilicon layer by the a-Si layer, thus, the manufacturing process is simplified. The source doping layer and the drain doping layer are obtained by doping in the polysilicon layer. In the present invention, doping ions in the polysilicon layer are formed, for example, by an excimer laser annealing, avoiding the defects and undesirable effects of the thin film transistor caused by the ion implanting in the prior art, thus the performance of the thin film transistor is improved.

Next, a method for manufacturing a low-temperature polysilicon thin film transistor and an array substrate according to exemplary embodiments of the present invention will be described particularly.

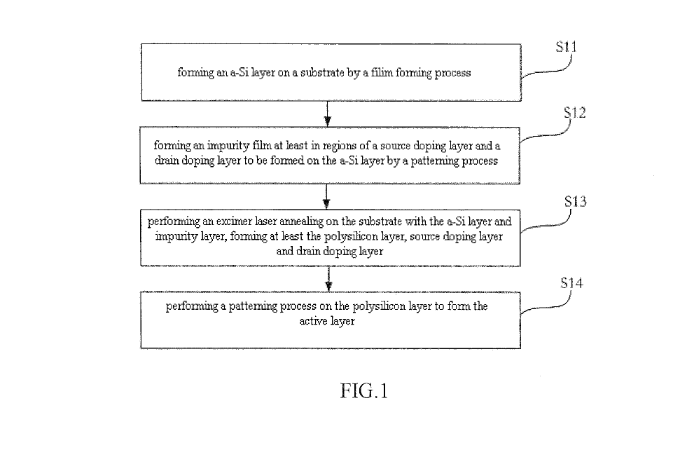

Referring to FIG. 1, a method for manufacturing a low-temperature polysilicon thin film transistor and array substrate according to an exemplary embodiment of the present invention comprises steps of:

S11. forming an a-Si layer on a substrate, for example, by a film forming process;

S12. forming an impurity film at least in regions of a source doping layer and a drain doping layer to be formed on the a-Si layer by a patterning process;

wherein in an alternative embodiment, a boron or phosphorus film layer with a predetermined thickness is formed on the a-Si layer by a thermal evaporation or sputtering method, and the impurity film corresponding to the regions of the source doping layer and the drain doping layer is left by the patterning process;

S13. converting the a-Si layer into a polysilicon layer, and ions in the impurity film being implanted into regions of the polysilicon layer contacting the impurity film during this conversion to form the source doping layer and the drain doping layer.

Specifically, an excimer laser annealing is performed on the a-Si layer and the impurity film, and a-Si is converted into polysilicon, then ions in the impurity film on the polysilicon layer are implanted into regions of the polysilicon layer contacting the impurity film, thus, the source doping layer is formed in regions corresponding to the source doping layer to be formed and the drain doping layer is formed in regions corresponding to the drain doping layer to be formed, a polysilicon layer is formed in regions except the source doping layer and the drain doping layer.

Alternatively, the excimer laser annealing is performed under conditions of: a laser pulse frequency being 100-400 Hz, a laser overlapping rate being 90%-98%, a laser pulse width being less than 100 ns and a laser energy density being 100-600 mJ/cm².

The method for manufacturing a low-temperature polysilicon thin film transistor further comprising a step:

S14. performing a patterning process on the polysilicon layer to form an active layer in a predetermined region.

Specifically, an active layer is formed in a predetermined region in a photoetching manner; during this process, a photoresist is used as a mask, and then a dry etching and a peeling of the photoresist are performed, thereafter, the polysilicon layer in regions corresponding to the active layer to be formed is left and the polysilicon layer in other regions is peeled.

It should be noted that the process for manufacturing the thin film transistor further comprises manufacturing a gate electrode and a gate insulating layer.

Further, the above method further comprises a step of: thermally annealing the a-Si layer after forming the a-Si layer and before forming the impurity film.

During the above process for manufacturing the thin film transistor according to an exemplary embodiment of the present invention, the source doping layer and the drain doping layer are formed during forming the polysilicon layer, specifically, the source doping layer and the drain doping layer are formed while the polysilicon is formed by the excimer laser annealing (ELA), thus the manufacturing process is simplified, moreover, doping ions forming the source doping layer and the drain doping layer are formed by the excimer laser annealing, which avoids the defects and undesirable effects of the thin film transistor caused by the ion implanting in the prior art, thus the performance of the thin film transistor is improved.

Embodiments of the present invention further provide a method for manufacturing an array substrate which comprises steps of: forming an a-Si layer on the substrate; forming an impurity film on the a-Si layer, positions of the impurity film correspond to a source doping layer to be formed, a drain doping layer to be formed and a bottom electrode of a storage capacitance to be formed, respectively; converting the a-Si layer into a polysilicon layer, and during this conversion, ions in the impurity film are implanted into regions of the polysilicon layer contacting the impurity film to form the source doping layer, the drain doping layer and the bottom electrode of the storage capacitance.

Alternatively, in the step of converting the a-Si layer into the polysilicon layer, an excimer laser annealing is performed on the a-Si layer and the impurity film to convert a-Si into polysilicon, ions in the impurity film in the polysilicon are implanted into regions of the polysilicon layer contacting the impurity layer, thus, the source doping layer is formed in regions corresponding to the source doping layer to be formed, and the drain doping layer is formed in regions corresponding to the drain doping layer to be formed, and the bottom electrode of the storage capacitance is formed in regions corresponding to the bottom electrode of the storage capacitance to be formed, and the polysilicon layer is formed in regions except the source doping layer, the drain doping layer and the bottom electrode of the storage capacitance.

Next, a manufacturing process for the array substrate according to the above embodiment of the present invention will be explained in detail with respect to the accompanying drawings.

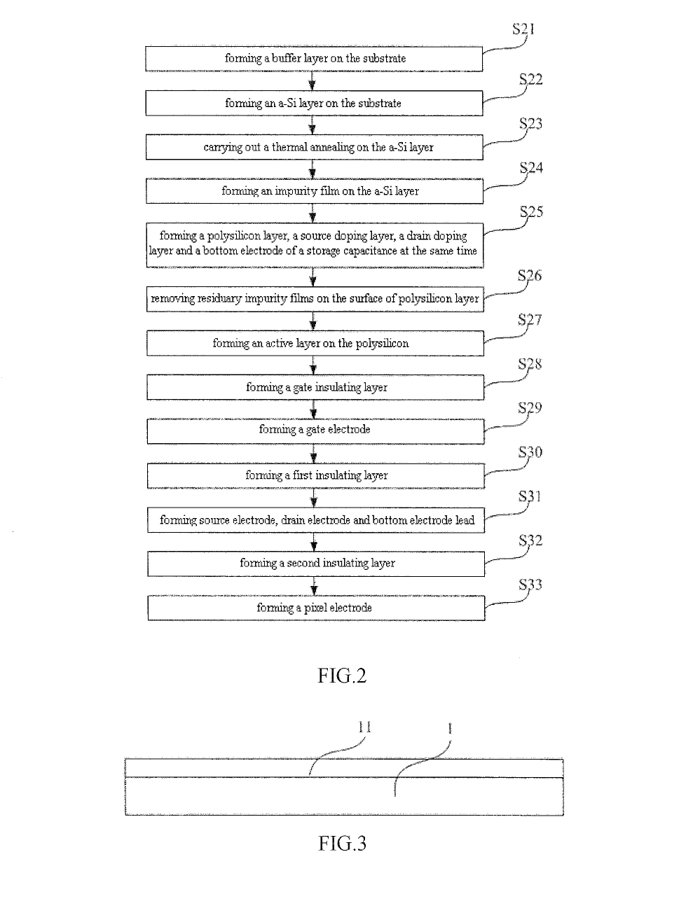

Referring to FIG. 2, a detailed flow chart of a manufacturing method for the array substrate is shown.

S21. forming a buffer layer on the substrate;

firstly, precleaning the substrate if the cleanness of the substrate does not meet requirements;

secondly, a buffer layer covering the entire substrate is formed on the substrate by a film forming process.

Specifically, a buffer layer 11 is formed on the substrate 1 as shown in FIG. 3.

The step S21 is an alternative step, the buffer layer formed in the step S21 may improve an attachment between the a-Si and the substrate, meanwhile may also prevent metallic ions in the substrate from diffusing into the source doping layer and the drain doping layer, thereby a defect center is lowered and a resultant leakage current may be decreased.

The substrate of the present invention is not limited to a specific material, it may be a glass substrate or a flexible substrate or the like.

As a specific implement, a buffer layer with a thickness in a range of 2000˜3000 Å is deposited on a glass substrate by using plasma enhanced chemical vapor deposition (PECVD); the deposition material may be a single SiOₓ film layer or SiNₓ film layer, or a lamination of SiOₓ and SiNₓ.

A reactant gas for forming the SiNₓ film layer may be a mixing gas of SiH₄, NH₃ and N₂, or a mixing gas of SiH₂Cl₂, NH₃ and N₂; a reactant gas for forming the SiOₓ film layer may be a mixing gas of SiH₄, NH₃ and O₂, or a mixing gas of SiH₂Cl₂, NH₃ and O₂.

S22. forming an a-Si layer on the substrate.

Specifically, an a-Si layer 12 as shown in FIG. 4 is formed on the buffer layer 11 as shown in FIG. 3 by the film forming process; alternatively, the buffer layer 11 covers the entire substrate 1.

Specifically, an a-Si layer with a thickness in a range of 300˜4000 Å is deposited on the substrate 1 (if a buffer layer is not formed on the substrate) or the buffer layer 11, the corresponding reactant gas may be a mixing gas of SiH₄ and H₂ or a mixing gas of SiH₂Cl₂ and H₂.

The a-Si layer formed in the step S22 will be used in the following step S25 to form a polysilicon layer.

S23. thermally annealing the a-Si layer.

The thermal annealing is carried out on the a-Si layer, such that hydrogen in the a-Si layer is removed and a hydrogen explosion is prevented from occurring in a subsequent step of laser annealing.

The step S23 is an alternative step.

S24. forming an impurity film on the a-Si layer.

The impurity film is formed at least in regions of the a-Si layer corresponding to the source doping layer to be formed and the drain doping layer to be formed by a film forming process.

Further, the impurity film is formed in regions corresponding to the bottom electrode of the storage capacitance to be formed, while the impurity film is formed in regions of the a-Si layer corresponding to the source doping layer to be formed and the drain doping layer to be formed by a film forming process.

Referring to FIG. 5, firstly, a boron (B) or phosphorus (P) film layer 13 is formed on the a-Si layer 12 by a thermal evaporation or magnetron sputtering method.

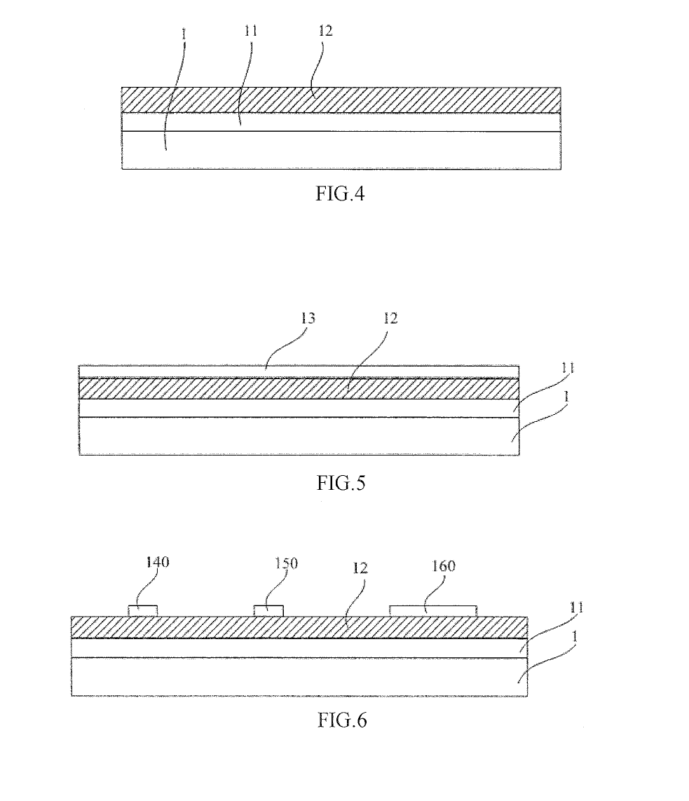

Referring to FIG. 6, secondly, a patterning process, such as photoresist coating, mask, exposure and development, photoetching and etching technique, is performed on the boron or phosphorus film layer 13, at least a boron (B) or phosphorus (P) film layer 140 in regions corresponding to the source doping layer to be formed, a boron (B) or phosphorus (P) film layer 150 in regions corresponding to the drain doping layer to be formed are left; further, a boron (B) or phosphorus (P) film layer 160 in regions corresponding to the bottom electrode of the storage capacitance to be formed is also left. The boron (B) or phosphorus (P) film layer is an impurity film.

Specifically, the boron (B) or phosphorus (P) film layer in non-doping regions is removed by using a photoresist layer as a mask in a wet etching manner. If only the source doping layer and the drain doping layer are formed on the polysilicon layer, the boron (B) or phosphorus (P) film layer in regions which do not correspond to the source and drain doping layer to be formed is removed. If the bottom electrode of the storage capacitance is also formed on the polysilicon layer, the boron (B) or phosphorus (P) film layer in regions corresponding to the bottom electrode of the storage capacitance to be formed is left. In the embodiment, the corresponding regions are regions which are right opposite to each other.

The bottom electrode of the storage capacitance is obtained by doping in the polysilicon, that is, foreign ions are doped in regions of the polysilicon layer corresponding to the bottom electrode of the storage capacitance, so that the polysilicon layer with a semiconductor property is converted into a conductive layer.

S25. forming a polysilicon layer, a source doping layer, a drain doping layer and a bottom electrode of a storage capacitance at the same time.

Referring to FIG. 7, an excimer laser annealing process is carried out on the substrate 1 on which the a-Si layer 12 and the impurity films (the film layers numbered 140 and 150, or also including the film layer numbered 160 as shown in FIG. 6) are formed, then the a-Si layer 12 is converted into a polysilicon layer 29, and ions in the impurity films above the polysilicon layer 29 are implanted into regions in the polysilicon layer 29 contacting the impurity films, wherein a source doping layer 14 is formed at least in regions corresponding to the source doping layer to be formed, a drain doping layer 15 is formed at least in regions corresponding to the drain doping layer to be formed and a bottom electrode 16 of a storage capacitance is formed at least in regions corresponding to the bottom electrode of the storage capacitance to be formed; regions except the source and drain doping layer are the polysilicon layer; or regions except the source doping layer, the drain doping layer and the bottom electrode of the storage capacitance are the polysilicon layer.

The excimer laser annealing according to the exemplary embodiment of the present invention may utilize an excimer laser (a wavelength of 308 nm) such as XeCl, KrF or ArF excimer laser, in which a laser beam is converted into a linear light source through an optical system.

Alternatively, the excimer laser annealing is performed under conditions of: a laser pulse frequency being 100-400 Hz, a laser overlapping rate being 90%-98%, a laser pulse width being less than 100 ns and a laser energy density being 100-600 mJ/cm².

Compared with the thermal annealing process, an excimer laser annealing process is used to convert a-Si into polysilicon in the present invention, in which it may be realized that a low-temperature polysilicon transistor is manufactured on a flexible substrate, and the transistor has a more stable performance.

During the excimer laser annealing process, a position of a laser beam is fixed, and the substrate is fixed on a displacement platform, a radiation region by the laser can be controlled by moving the substrate, so that the laser beam scans a predetermined region of the substrate. The a-Si, B molecule or P molecule under the irradiation of the laser absorbs the laser energy to be melted, then the B molecule or P molecule diffuses into the melted silicon, thereafter, during a cooling process, the a-Si is converted into the polysilicon while the laser facilitates the doping to form a polysilicon region doped with B ions or P ions, which forms the source doping layer and the drain doping layer. During this process, because the a-Si, B molecule or P molecule under the irradiation of the laser absorbs the laser energy to be melted, the B molecule or P molecule diffuses into the melted silicon at a high rate, and a distribution density of the B molecule or P molecule close to the silicon layer surface is close to that away from the silicon layer surface, namely, a gradient of the distribution density of the B molecule or P molecule from a surface to a bottom of the silicon layer is small, thereby the formed source doping layer and drain doping layer have a good conductivity.

After the photoresist is peeled in step S24, the B or P film layers 140, 150 as shown in FIG. 6 in regions corresponding to the source doping layer 14 and drain doping layer 15 as shown in FIG. 7 and the B or P film layer 160 as shown in FIG. 6 in regions corresponding to the bottom electrode 16 of the storage capacitance as shown in FIG. 7 can be implanted into a layer near the surface of the polysilicon layer, thereby the source doping layer 14, the drain doping layer 15 and the bottom electrode 16 of the storage capacitance as shown in FIG. 7 are formed.

During this process, a high temperature occurs on or near the surface of the a-Si layer due to the scanning of the laser with a high energy, and when the excimer laser annealing is performed under conditions of a laser pulse frequency of 100-400 Hz, a laser overlapping rate of 90%-98%, a laser pulse width less than 100 ns and a laser energy density of 100-600 mJ/cm², boron (B) or phosphorus (P) implanted into the polysilicon layer can be activated, thus it is not required to activate the boron (B) or phosphorus (P) by the thermal annealing.

In the prior art, during the bombarding implantation to the polysilicon by a high energy ion beam, i.e. ion implantation process, the crystal lattice is damaged due to the bombardment, thus a subsequent thermal annealing process is required to recovery the crystal lattice. In the present invention, an excimer laser annealing is used to implant the boron (B) or phosphorus (P) gradually, namely, the boron (B) or phosphorus (P) is implanted into the surface of the polysilicon layer gradually, which ensures an integrity of crystal lattice.

Moreover, during the excimer laser annealing, the B molecule or P molecule absorbs the laser energy under the laser irradiation to be activated, which can function as a donor or an acceptor well, thus a subsequent step in which the B molecule or P molecule is activated by a thermal annealing process is not required.

In the present invention, by one excimer laser annealing process, the polysilicon layer, the source doping layer and the drain doping layer are formed, or the polysilicon layer, the source doping layer, the drain doping layer and the bottom electrode of the storage capacitance are formed. Thus, a good performance of the thin film transistor is ensured while the manufacturing process is simplified.

The thickness of the above impurity film can be controlled, so that ions in the impurity film are completely implanted into the polysilicon layer after the excimer laser annealing process, namely, there is not any residuary impurity film on the polysilicon layer. If there are some residuary impurity films on the polysilion layer after the excimer laser annealing process, a step S26 needs to be performed.

S26. removing residuary impurity films from the surface of the polysilicon layer.

The residuary boron (B) or phosphorus (P) on the surface of the polysilicon layer is completely removed by etching, avoiding that the residuary boron (B) or phosphorus (P) affects the performance of the thin film transistor.

S27. forming an active layer on the polysilicon.

The active layer is also referred as a polysilicon island layer.

Based on the step S26 or S25, a patterning process is performed on the polysilicon layer to form the active layer.

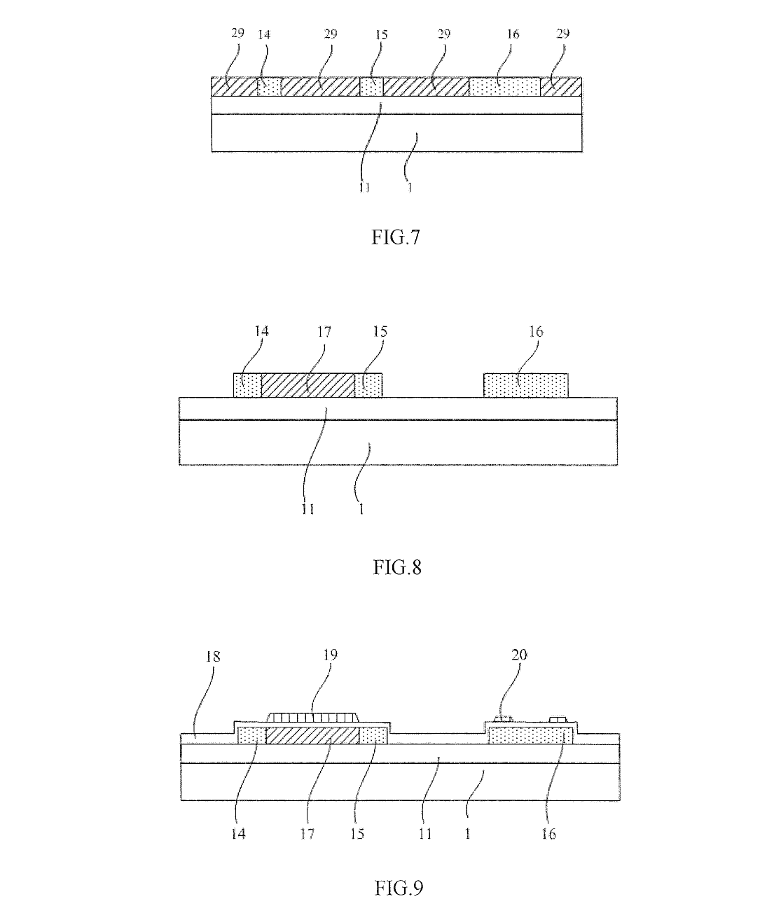

Referring to FIG. 8, in a specific implement, an active layer 17 in a predetermined region is formed by photoetching; in particular, a photoresist is used as a mask, after dry etching and photoresist peeling, only the polysilicon layer in regions corresponding to the active layer 17 to be formed is left and the polysilicon layer in other regions is peeled.

Further, the forming process for the above array substrate according to the present invention may also comprise steps S28-S33.

S28. forming a gate insulating layer.

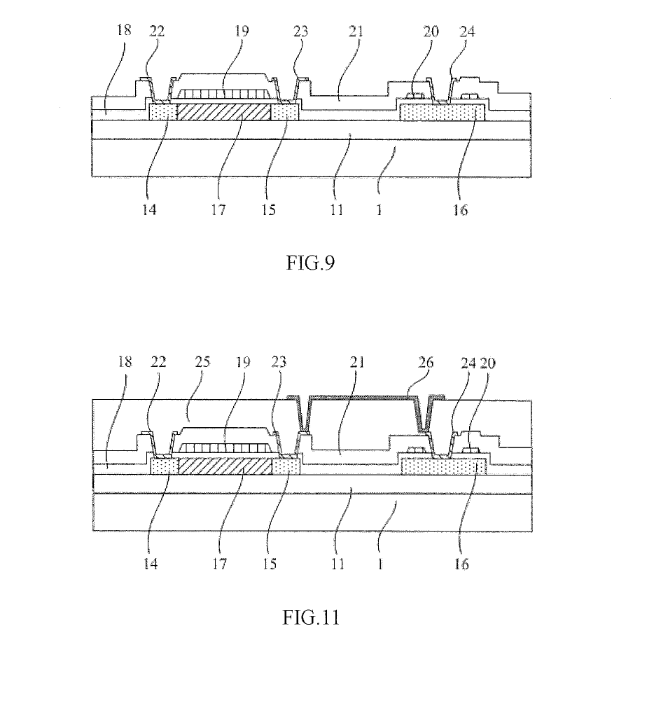

Referring to FIG. 9, a gate insulating layer (GI) 18 is deposited by PECVD, a thickness of the gate insulating layer is 1000-2000 Å, and the gate insulating layer may be a layer of SiNₓ or a lamination of SiNₓ and SiOₓ.

S29. forming a gate electrode.

Referring to FIG. 9, a gate metal or alloy layer with a thickness of 1500-2500 Å is deposited by a sputter method, the metal or alloy layer may be formed of Mo, Al, Cu or W, or formed of an alloy including at least two of Mo, Al, Cu or W. Then, a pattern of the gate electrode 19 is formed by a patterning process. Further, a top electrode pattern 20, which is right above the bottom electrode of the storage capacitance and used to form the storage capacitance with the bottom electrode of the storage capacitance, may be also formed at the same time.

S30. forming a first insulating layer.

The first insulating layer which is a first insulating layer 21 as shown in FIG. 10 is above the gate electrode and covers the entire substrate.

Specifically, an insulating layer with a thickness of 1000-3000 Å is deposited by PECVD, the insulating layer may have components of SiNₓ or SiOₓ; then a photoetching and a dry etching are performed, finally via holes for connecting to the source doping layer 14, the drain doping layer 15 and the bottom electrode 16 of the storage capacitance are formed.

S31. forming a source electrode, a drain electrode and a bottom electrode lead.

A metal or alloy layer with a thickness of 2000-3000 Å is deposited by a sputtering or thermal evaporation method, the material of the metal or alloy layer may be selected from a metal such as Mo, Al, Cu or W, or an alloy of several above metals, after a photoetching and etching, a source electrode 22, a drain electrode 23 and a bottom electrode lead 24 of the storage capacitance as shown in FIG. 10 are formed. The source electrode 22 and the drain electrode 23 are electrically connected to the source doping layer 14 and the drain doping layer 15 as shown in FIG. 10, respectively.

S32. forming a second insulating layer.

As shown in FIG. 11, a second insulating layer 25 is positioned above the source electrode 22, the drain electrode 23 and the bottom electrode lead 24. Specifically, the second insulating with a thickness of 1000-3000 Å is deposited by PECVD, the second insulating layer may have components of SiNₓ or SiOₓ; then a photoetching and a dry etching are performed, finally via holes for connecting to the drain electrode 23 and the bottom electrode lead 24 are formed. The second insulating layer can also be replaced with a photosensitive insulating resin.

S33. forming a pixel electrode.

Referring to FIG. 11, a pixel electrode 26 is formed on the second insulating layer 25 and is connected to the drain electrode 23 and the bottom electrode 16 of the storage capacitance through the via holes. Specifically, a transparent conductive film with a thickness of 500-1500 Å is deposited by a magnetron sputtering device and may consist of components such as ITO, IZO or AZO, then an exposure process by a common mask plate, a development and a wet etching are carried out, the pixel electrode is thus produced, the pixel electrode may be a pixel electrode in various types of display devices, for example, the pixel electrode is a pixel electrode in pixels corresponding to a common electrode if the display device is a liquid crystal display device; the pixel electrode is an anode in the OLED if the display device is an OLED, of course, the pixel electrode may also be a cathode or the like as required, here the pixel electrode is not limited to a specific electrode.

In the method for manufacturing the low-temperature polysilicon thin film transistor according to the exemplary embodiment of the present invention, the source doping layer and the drain doping layer are formed while the polysilicon layer is formed, specifically, the source doping layer and the drain doping layer are formed while the polysilicon layer is formed by the excimer laser annealing process, thus the manufacturing process is simplified, moreover, doping ions forming the source doping layer and the drain doping layer are formed by the excimer laser annealing, which avoids the defects and undesirable effects of the thin film transistor caused by the ion implanting in the prior art, thus the performance of the thin film transistor is improved.

Obviously, those skilled in the art can make various changes and modifications to the present invention without departing from the spirit and scope of the present invention. Thereby, the present invention is intended to include these changes and modifications if these changes and modifications fall into the scope of appended claims and equivalents thereof.

What is claimed is:

1. A method for manufacturing a low-temperature polysilicon thin film transistor comprising steps of:
forming an a-Si layer on a substrate;
forming an impurity film on the a-Si layer, positions of the impurity film corresponding to a source doping layer to be formed and a drain doping layer to be formed respectively; and
converting the a-Si layer into a polysilicon layer, and during the conversion from the a-Si layer into the polysilicon layer, ions in the impurity film being implanted into regions in the polysilicon layer contacting with the impurity film to form the source doping layer and the drain doping layer.

2. The method according to claim 1, wherein:
in the step of the conversion from the a-Si layer into the polysilicon layer, an excimer laser annealing process is performed on the a-Si layer and the impurity film, so that the source doping layer is formed in a region corresponding to the source doping layer to be formed, the drain doping layer is formed in a region corresponding to the drain doping layer to be formed and the polysilicon layer is formed in regions except the source doping layer and the drain doping layer.

3. The method according to claim 2, wherein:
the excimer laser annealing process is performed under conditions of: a laser pulse frequency being 100-400 Hz, a laser overlapping rate being 90%-98%, a laser pulse width being less than 100 ns and a laser energy density being 100-600 mJ/cm².

4. The method according to claim 2, further comprising a step of:
patterning the polysilicon layer to form an active layer in a predetermined region.

5. The method according to claim 1, further comprising a step of :
thermally annealing the a-Si layer, wherein the step of thermally annealing the a-Si layer is after the step of forming the a-Si layer and before the step of forming the impurity film.

6. The method according to claim 1, wherein the step of forming the impurity film comprises steps of:
forming a boron film or phosphorus film on the a-Si layer by a thermal evaporation or sputtering method; and
forming the impurity film by leaving, by a patterning process, the boron film or phosphorus film in regions corresponding to the source doping layer and drain doping layer.

7. The method according to claim 6, wherein:
the thickness of the boron film or phosphorus film is controlled or selected such that ions in the boron film or phosphorus film are completely implanted into the polysilicon layer.

8. The method according to claim 1, further comprising a step of:
removing redundant impurity film from the surface of the polysilcion layer after forming the source doping layer and the drain doping layer.

9. The method according to claim 1, wherein the step of forming the a-Si layer on the substrate comprises a step of:
depositing the a-Si layer on a buffer layer formed on the substrate or directly on the substrate by a film forming process.

10. A method for manufacturing an array substrate comprising steps of:
forming an a-Si layer on a substrate;
forming an impurity film on the a-Si layer, positions of the impurity film corresponding to a source doping layer to be formed, a drain doping layer to be formed and a bottom electrode of a storage capacitance to be formed respectively;
converting the a-Si layer into a polysilicon layer, and during the conversion from the a-Si layer into the polysilicon layer, ions in the impurity film being implanted into regions in the polysilicon layer contacting with the impurity film to form the source doping layer, the drain doping layer and the bottom electrode of the storage capacitance.

11. The method according to claim 10, wherein:
in the step of the conversion from the a-Si layer into the polysilicon layer, an excimer laser annealing process is performed on the a-Si layer and the impurity film, so that the source doping layer is formed in a region corresponding to the source doping layer to be formed, the drain doping layer is formed in a region corresponding to the drain doping layer to be formed, the bottom electrode of the storage capacitance is formed in a region corresponding to the bottom electrode of the storage capacitance to be formed and the polysilicon layer is formed in regions except the source doping layer, the drain doping layer and the bottom electrode of the storage capacitance.

12. The method according to claim 11, wherein:
the excimer laser annealing process is performed under conditions of: a laser pulse frequency being 100-400 Hz, a laser overlapping rate being 90%-98%, a laser pulse width being less than 100 ns and a laser energy density being 100-600 mJ/cm².

13. The method according to claim 11, further comprising a step of:
patterning the polysilicon layer to form an active layer in a predetermined region.

14. The method according to claim 10, further comprising a step of:
thermally annealing the a-Si layer, wherein the step of thermally annealing the a-Si layer is after the step of forming the a-Si layer and before the step of forming the impurity film.

15. The method according to claim 10, wherein the step of forming the impurity film comprises steps of:
forming a boron film or phosphorus film on the a-Si layer by a thermal evaporation or sputtering method; and
forming the impurity film by leaving, by a patterning process, the boron film or phosphorus film in regions corresponding to the source doping layer, the drain doping layer and the bottom electrode of the storage capacitance.

16. The method according to claim 15, wherein:
the thickness of the boron film or phosphorus film is controlled or selected such that ions in the boron film or phosphorus film are completely implanted into the polysilicon layer.

17. The method according to claim 10, further comprising a step of:
removing the redundant impurity film from the surface of the polysilcion layer after forming the source doping layer, the drain doping layer and the bottom electrode of the storage capacitance.

18. The method according to claim 10, wherein the step of forming the a-Si layer on the substrate comprises a step of:
depositing the a-Si layer on a buffer layer formed on the substrate or directly on the substrate by a film forming process.

19. The method according to claim 13, further comprising steps of:
depositing a gate insulating layer on the polysilicon layer, the source doping layer, the drain doping layer and the bottom electrode of the storage capacitance;
forming a gate electrode and a top electrode of the storage capacitance on the gate insulating layer;
depositing a first insulating layer on the gate insulating layer, the gate electrode and the top electrode of the storage capacitance, and forming via holes connected to the source doping layer, the drain doping layer and the bottom electrode of the storage capacitance, respectively;
depositing conductive layers at via holes respectively to form a source electrode, a drain electrode and a bottom electrode lead, wherein the source electrode, the drain electrode and a bottom electrode lead are electrically connected to the source doping layer, the drain doping layer and the bottom electrode of the storage capacitance respectively;
forming a second insulating layer on the source electrode, the drain electrode, the bottom electrode lead and the first insulating layer, and forming via holes contacting the drain electrode and the bottom electrode lead; and
depositing a conductive layer to form a pixel electrode in an electric connection with the drain source and the bottom electrode lead.

20. A method for manufacturing a low-temperature polysilicon thin film transistor comprising a step of:
forming a source doping layer and a drain doping layer while forming a polysilicon layer.
